(19) United States
(12) Patent Application Publication
(10) Pub. No.: US 2004/0117717 A1
(43) Pub. Date: Jun. 17, 2004

(54) Apparatus and method for a flush procedure in an interrupted trace stream

(76) Inventor: Gary L. Swoboda, Sugar land, TX (US)

Correspondence Address: TEXAS INSTRUMENTS INCORPORATED, P O BOX 655474, M/S 3999, DALLAS, TX, 75265

(21) Appl. No.: 10/729,407

(22) Filed: Dec. 5, 2003

Related U.S. Application Data
(60) Provisional application No. 60/434,211, filed on Dec. 17, 2002.

(51) Int. Cl. H03M 13/00

(52) U.S. Cl. 714/776

(57) ABSTRACT

In a trace stream system test and debug system, the trace packets are reformatted into export trace packets for transmission to the test processing unit. After a halt signal is generated during execution of a non-interruptible code segment, trace elements can be generated that do not complete the export trace element after conversion. A flush mechanism is used to transfer the incomplete export trace packets to the test apparatus. The export trace packets are continued until sufficient export trace packets have been generated to fill a destination memory location.

### RELATED APPLICATION

This application claims priority under 35 USC §119(e) (1) of Provisional Application No. 60/434,211 (TI-34659P) filed Dec. 17, 2002.

U.S. patent application (Attorney Docket No. TI-34654), entitled APPARATUS AND METHOD FOR SYNCHRONIZATION OF TRACE STREAMS FROM MULTIPLE PROCESSORS, invented by Gary L. Swoboda, filed on even date herewith, and assigned to the assignee of the present application; U.S. patent application (Attorney Docket No. TI-34655), entitled APPARATUS AND METHOD FOR SEPARATING DETECTION AND ASSERTION OF A TRIGGER EVENT, invented by Gary L. Swoboda, filed on even date herewith, and assigned to the assignee of the present application; U.S. patent application (Attorney Docket No. TI-34656), entitled APPARATUS AND METHOD FOR STATE SELECTABLE TRACE STREAM GENERATION, invented by Gary L. Swoboda, filed on even date herewith, and assigned to the assignee of the present application; U.S. patent application (Attorney Docket No. TI-34657), entitled APPARATUS AND METHOD FOR SELECTING PROGRAM HALTS IN AN UNPROTECTED PIPELINE AT NON-INTERRUPTIBLE POINTS IN CODE EXECUTION, invented by Gary L. Swoboda and Krishna Allam, filed on even date herewith, and assigned to the assignee of the present application; U.S. patent application (Attorney Docket No. TI-34658), entitled APPARATUS AND METHOD FOR REPORTING PROGRAM HALTS IN AN UNPROTECTED PIPELINE AT NON-INTERRUPTIBLE POINTS IN CODE EXECUTION, invented by Gary L. Swoboda, filed on even date herewith, and assigned to the assignee of the present application; U.S. patent application (Attorney Docket No. TI-34660), entitled APPARATUS AND METHOD FOR CAPTURING AN EVENT OR COMBINATION OF EVENTS RESULTING IN A TRIGGER SIGNAL IN A TARGET PROCESSOR, invented by Gary L. Swoboda, filed on even date herewith, and assigned to the assignee of the present application; U.S. patent application (Attorney Docket No. TI-34661), entitled APPARATUS AND METHOD FOR CAPTURING THE PROGRAM COUNTER ADDRESS ASSOCIATED WITH A TRIGGER SIGNAL IN A TARGET PROCESSOR, invented by Gary L. Swoboda, filed on even date herewith, and assigned to the assignee of the present application; U.S. patent application (Attorney Docket No. TI-34662), entitled APPARATUS AND METHOD DETECTING ADDRESS CHARACTERISTICS FOR USE WITH A TRIGGER GENERATION UNIT IN A TARGET PROCESSOR, invented by Gary Swoboda and Jason L. Peck, filed on even date herewith, and assigned to the assignee of the present application; U.S. patent application (Attorney Docket No. TI-34663), entitled APPARATUS AND METHOD FOR TRACE STREAM IDENTIFICATION OF A PROCESSOR RESET, invented by Gary L. Swoboda, Bryan Thome and Manisha Agarwala, filed on even date herewith, and assigned to the assignee of the present application; U.S. patent (Attorney Docket No. TI-34664), entitled APPARATUS AND METHOD FOR TRACE STREAM IDENTIFICATION OF A PROCESSOR DEBUG HALT SIGNAL, invented by Gary L. Swoboda, Bryan Thome, Lewis Nardini and Manisha Agarwala, filed on even date herewith, and assigned to the assignee of the present application; U.S. patent application (Attorney Docket No. TI-34665), entitled APPARATUS AND METHOD FOR TRACE STREAM IDENTIFICATION OF A PIPELINE FLATTENER PRIMARY CODE FLUSH FOLLOWING INITIATION OF AN INTERRUPT SERVICE ROUTINE; invented by Gary L. Swoboda, Bryan Thome and Manisha Agarwala, filed on even date herewith, and assigned to the assignee of the present application; U.S. patent application (Attorney Docket No. TI-34666), entitled APPARATUS AND METHOD FOR TRACE STREAM IDENTIFICATION OF A PIPELINE FLATTENER SECONDARY CODE FLUSH FOLLOWING A RETURN TO PRIMARY CODE EXECUTION, invented by Gary L. Swoboda, Bryan Thome and Manisha Agarwala filed on even date herewith, and assigned to the assignee of the present application; U.S. patent application (Docket No. TI-34667), entitled APPARATUS AND METHOD IDENTIFICATION OF A PRIMARY CODE START SYNC POINT FOLLOWING A RETURN TO PRIMARY CODE EXECUTION, invented by Gary L. Swoboda, Bryan Thome and Manisha Agarwala, filed on even date herewith, and assigned to the assignee of the present application; U. S. patent application (Attorney Docket No. TI-34668), entitled APPARATUS AND METHOD FOR IDENTIFICATION OF A NEW SECONDARY CODE START POINT FOLLOWING A RETURN FROM A SECONDARY CODE EXECUTION, invented by Gary L. Swoboda, Bryan Thome and Manisha Agarwala, filed on even date herewith, and assigned to the assignee of the present application; U.S. patent application (Attorney Docket No. TI-34669), entitled APPARATUS AND METHOD FOR TRACE STREAM IDENTIFICATION OF A PAUSE POINT IN A CODE EXECTION SEQUENCE, invented by Gary L. Swoboda, Bryan Thome and Manisha Agarwala, filed on even date herewith, and assigned to the assignee of the present application; U.S. patent application (Attorney Docket No. TI-34670), entitled APPARATUS AND METHOD FOR COMPRESSION OF A TIMING TRACE STREAM, invented by Gary L. Swoboda and Bryan Thome, filed on even date herewith, and assigned to the assignee of the present application; U.S. patent application (Attorney Docket No. TI-34671), entitled APPARATUS AND METHOD FOR TRACE STREAM IDENTIFCATION OF MULTIPLE TARGET PROCESSOR EVENTS, invented by Gary L. Swoboda and Bryan Thome, filed on even date herewith, and assigned to the assignee of the present application; and U.S. patent application (Attorney Docket No. TI-34672 entitled APPARATUS AND METHOD FOR OP CODE EXTENSION IN PACKET GROUPS TRANSMITTED IN TRACE STREAMS, invented by Gary L. Swoboda and Bryan Thome, filed on even date herewith, and assigned to the assignee of the present application are related applications.

### BACKGROUND OF THE INVENTION

1. Field of the Invention

This invention relates generally to the testing of digital signal processing units and, more particularly, to the inclusion in the trace data streams of signals identifying selected events in the digital signal processors under test. These selected events are communicated to the testing apparatus by signal groups. In transferring test and debug data from the target processor to the host processing unit, the data is arranged in packets. The trace packets are formatted into export packets for the actual transfer from the target processor.

2. Description of the Related Art

As microprocessors and digital signal processors have become increasingly complex, advanced techniques have been developed to test these devices. Dedicated apparatus is available to implement the advanced techniques. Referring to FIG. 1A, a general configuration for the test and debug of a target processor is shown. The test and debug procedures operate under control of a host processing unit 10. The host processing unit 10 applies control signals to the emulation unit 11 and receives (test) data signals from the emulation unit 11 by cable connector 14. The emulation unit 11 applies control signals to and receives (test) signals from the target processing unit 12 by connector cable 15. The emulation unit 11 can be thought of as an interface unit between the host processing unit 10 and the target processor 12. The emulation unit 11 must process the control signals from the host processor unit 10 and apply these signals to the target processor 12 in such a manner that the target processor will respond with the appropriate test signals. The test signals from the target processor 12 can be a variety types. Two of the most popular test signal types are the JTAG (Joint Test Action Group) signals and trace signals. The JTAG signal provides a standardized test procedure in wide use. Trace signals are signals from a multiplicity of junctions in the target processor 12. While the width of the bus interfacing to the host processing unit 10 generally have a standardized width, the bus between the emulation unit 11 and the target processor 12 can be increased to accommodate the increasing complexity of the target processing unit 12. Thus, part of the interface function between the host processing unit 10 and the target processor 12 is to store the test signals until the signals can be transmitted to the host processing unit 10.

The data in trace stream that is transferred from the target processor to the host processing unit are originally formed in (10-bit) trace packets. In the example provided by FIG. 1B, the trace packets have two control bits and 8-bit payload. However, in the actual transmission from the target processor to the host processing unit, the 10-bit packets are arranged in 3-bit export packets, the 3-bit export trace packets being reassembled into 10-bit trace packets by the emulation unit or the host processing unit. Referring to FIG. 1C, the process of converting the 10-bit trace packets to the 3-bit trace packets is illustrated. The 10-bit trace packets in the first column are converted to the 3-bit export trace packets of the second column. The third column indicates the number of bits that are carried forward form a 10-bit trace packet after each export trace packet is formed. The four 10-bit trace packets can contain a 32-bit word, i.e., in the 4 8-bit payloads. Also shown in FIG. 1C is the effect of halting code execution in the target processor during a non-interruptible code segment. The code will keep executing until a suitable point has been reached. However, when the last portion of the 32-bit word from the non-interruptible code segment is finished, although the segment has been completed, one bit of data remains to be transmitted.

A need has been felt for apparatus and an associated method having the feature that data associated with an incomplete export trace packet can be transmitted to a host processing unit. It would be yet another feature of the apparatus and associated method to transmit all of the data generated during a non-interruptible code execution halt to the testing apparatus. It would be yet another feature of the apparatus and associated method to accommodate a non-interruptible code halt in the export trace stream. It would be a still further feature of the present invention to provide export packets that fill a storage location.

### SUMMARY OF THE INVENTION

The aforementioned and other features are accomplished, according to the present invention, by providing a control signal that is activated when a non-interruptible code execution receives a halt signal and the control signal is removed when the debug software directs the code to execute. The control signal is applied to the unit providing the export trace signals. When the control signal is active and when an incomplete export trace packet is ready for transmission, the control signal causes the export trace packet to filled and transmitted to the testing apparatus. In addition, the presence of the control signal ensures that the export packet transmitted will contain as many data bits as would be present in the export of a trace packet signal group, the trace packet signal group size being determined by the memory location in which the trace stream data will be stored. Other features and advantages of present invention will be more clearly understood upon reading of the following description and the accompanying drawings and the claims.

### BRIEF DESCRIPTION OF THE DRAWINGS

FIG. 1A is a general block diagram of a system configuration for test and debug of a target processor, while FIG. 1B illustrates the format of a trace packet; and

FIG. 1C illustrates the conversion from trace packets to export trace packets according to the prior art.

FIG. 2 is a block diagram of selected components in the target processor used the testing of the central processing unit of the target processor according to the present invention.

FIG. 3 is a block diagram of selected components of the illustrating the relationship between the components transmitting trace streams in the target processor.

FIG. 4A illustrates format by which the timing packets are assembled according to the present invention, while FIG. 4B illustrates the inclusion of a periodic sync ID packet in the timing trace stream.

FIG. 5 illustrates the parameters for sync markers in the program counter stream packets according to the present invention.

FIG. 6A illustrates the sync markers in the program counter trace stream when a periodic sync point ID is generated, while FIG. 6B illustrates the reconstruction of the target processor operation from the trace streams according to the present invention.

FIG. 7 is a block diagram illustrating the apparatus used in reconstructing the processor operation from the trace streams according to the present invention.

FIG. 8 is block diagram of the apparatus for converting group of trace packets to export packet when the trace packet is incomplete according to the present invention.

FIG. 9 illustrates the conversion of the trace packets to export packets according to the present invention.

### DESCRIPTION OF THE PREFERRED EMBODIMENT

1. Detailed Description of the Figures

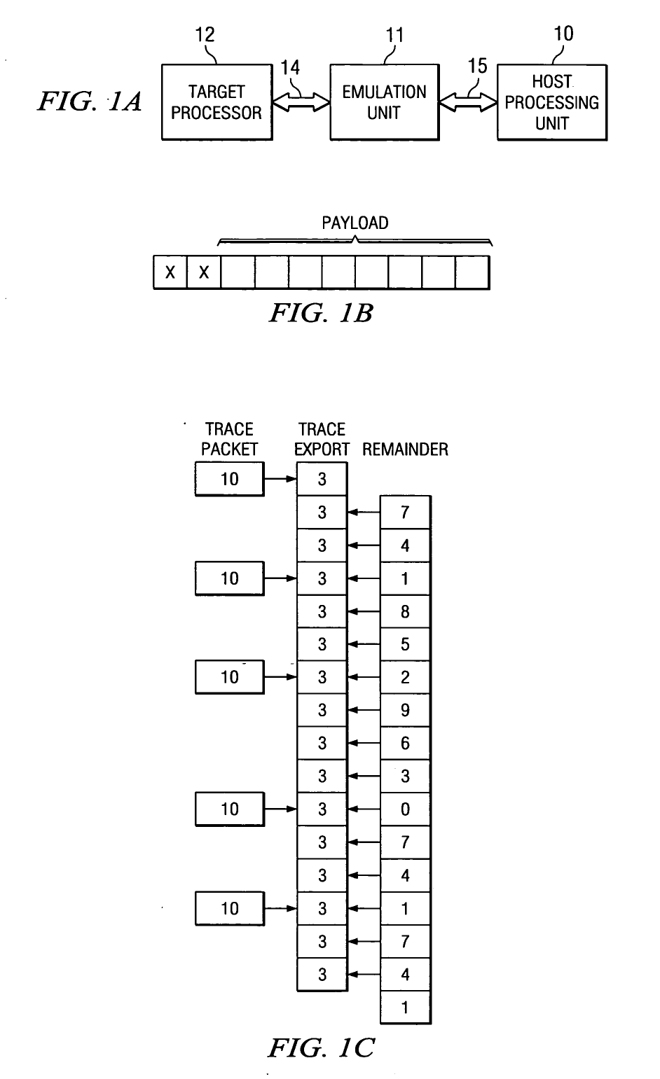

FIG. 1A, FIG. 1B and FIG. 1C been described with respect to the related art.

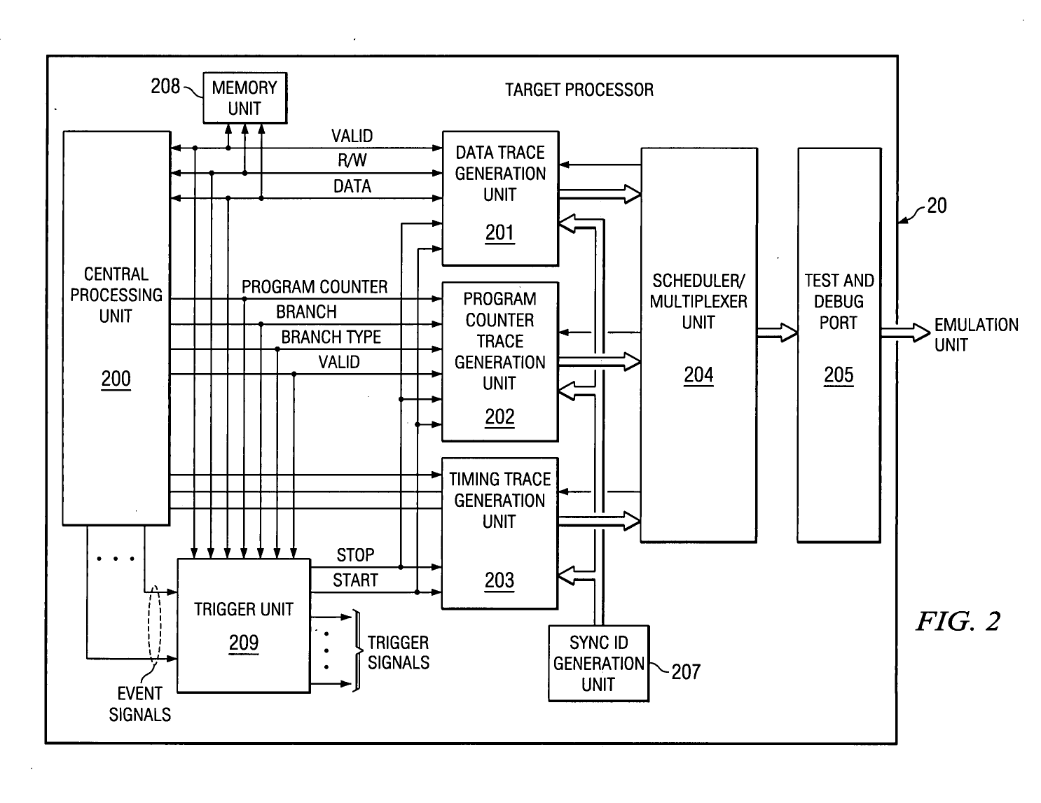

Referring to FIG. 2, a block diagram of selected components of a target processor 20, according to the present invention, is shown. The target processor includes at least one central processing unit 200 and a memory unit 208. The central processing unit 200 and the memory unit 208 are the components being tested. The trace system for testing the central processing unit 200 and the memory unit 202 includes three packet generating units, a data packet generation unit 201, a program counter packet generation unit 202 and a timing packet generation unit 203. The data packet generation unit 201 receives VALID signals, READ/WRITE signals and DATA signals from the central processing unit 200. After placing the signals in packets, the packets are applied to the scheduler/multiplexer unit 204 and forwarded to the test and debug port 205 for transfer to the emulation unit 11. The program counter packet generation unit 202 receives PROGRAM COUNTER signals, VALID signals, BRANCH signals, and BRANCH TYPE signals from the central processing unit 200 and, after forming these signal into packets, applies the resulting program counter packets to the scheduler/multiplexer 204 for transfer to the test and debug port 205. The timing packet generation unit 203 receives ADVANCE signals, VALID signals and CLOCK signals from the central processing unit 200 and, after forming these signal into packets, applies the resulting packets to the scheduler/multiplexer unit 204 and the scheduler/multiplexer 204 applies the packets to the test and debug port 205. Trigger unit 209 receives EVENT signals from the central processing unit 200 and signals that are applied to the data trace generation unit 201, the program counter trace generation unit 202, and the timing trace generation unit 203. The trigger unit 209 applies TRIGGER and CONTROL signals to the central processing unit 200 and applies CONTROL (i.e., STOP and START) signals to the data trace generation unit 201, the program counter generation unit 202, and the timing trace generation unit 203. The sync ID generation unit 207 applies signals to the data trace generation unit 201, the program counter trace generation unit 202 and the timing trace generation unit 203. While the test and debug apparatus components are shown as being separate from the central processing unit 201, it will be clear that an implementation these components can be integrated with the components of the central processing unit 201.

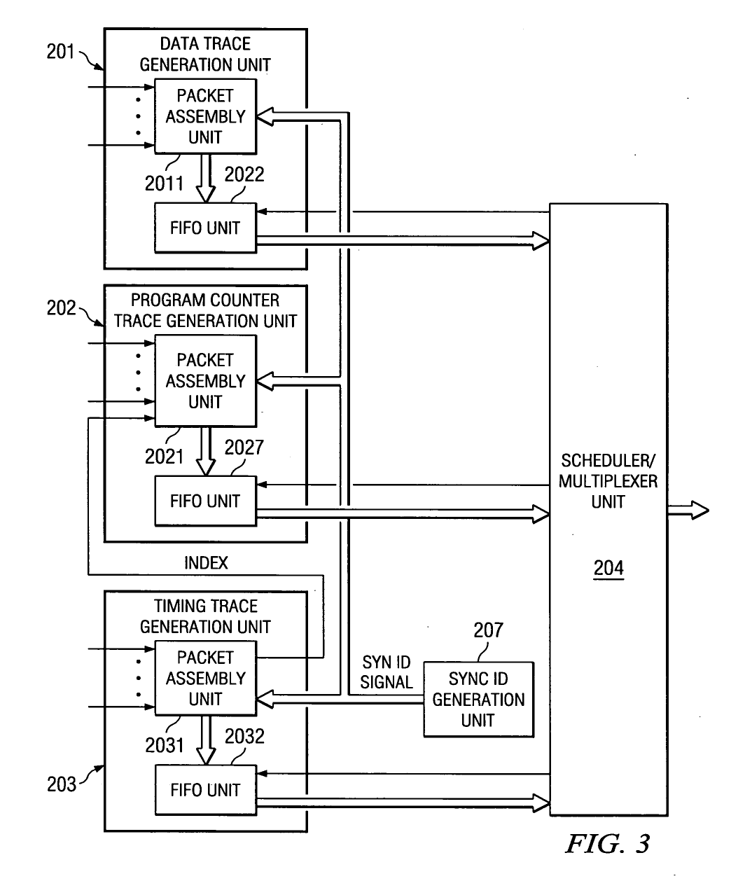

Referring to FIG. 3, the relationship between selected components in the target processor 20 is illustrated. The data trace generation unit 201 includes a packet assembly unit 2011 and a FIFO (first in/first out) storage unit 2012, the program counter trace generation unit 202 includes a packet assembly unit 2021 and a FIFO storage unit 2022, and the timing trace generation unit 203 includes a packet generation unit 2031 and a FIFO storage unit 2032. As the signals are applied to the packet generators 201, 202, and 203, the signals are assembled into packets of information. The packets in the preferred embodiment are 10 bits in width. Packets are assembled in the packet assembly units in response to input signals and transferred to the associated FIFO unit. The scheduler/multiplexer 204 generates a signal to a selected trace generation unit and the contents of the associated FIFO storage unit are transferred to the scheduler/multiplexer 204 for transfer to the emulation unit. Also illustrated in FIG. 3 is the sync ID generation unit 207. The sync ID generation unit 207 applies an SYNC ID signal to the packet assembly unit of each trace generation unit. The periodic signal, a counter signal in the preferred embodiment, is included in a current packet and transferred to the associated FIFO unit. The packet resulting from the SYNC ID signal in each trace is transferred to the emulation unit and then to the host processing unit. In the host processing unit, the same count in each trace stream indicates that the point at which the trace streams are synchronized. In addition, the packet assembly unit 2031 of the timing trace generation unit 203 applies and INDEX signal to the packet assembly unit 2021 of the program counter trace generation unit 202. The function of the INDEX signal will be described below.

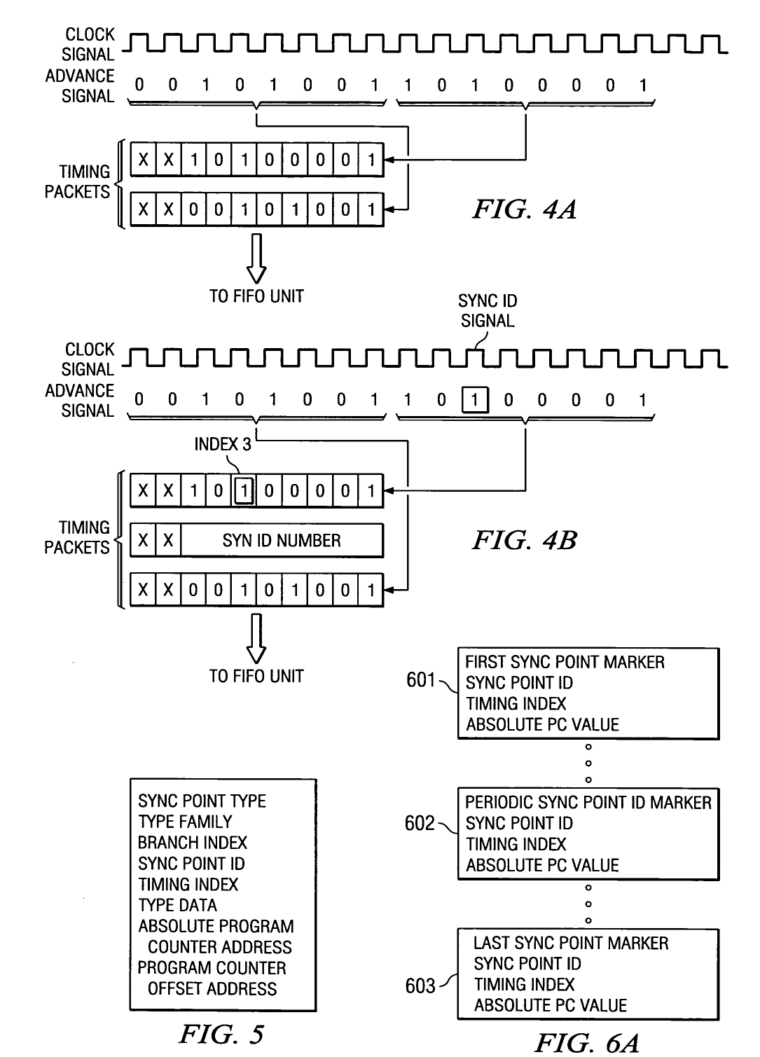

Referring to FIG. 4A, the assembly of timing packets is illustrated. The signals applied to the timing trace generation unit 203 are the CLOCK signals and the ADVANCE signals. The CLOCK signals are system clock signals to which the operation of the central processing unit 200 is synchronized. The ADVANCE signals indicate an activity such as a pipeline advance or program counter advance (()) or a pipeline non-advance or program counter non-advance (1). An ADVANCE or NON-ADVANCE signal occurs each clock cycle. The timing packet is assembled so that the logic signal indicating ADVANCE or NON-ADVANCE is transmitted at the position of the concurrent CLOCK signal. These combined CLOCK/ADVANCE signals are divided into groups of 8 signals, assembled with two control bits in the packet assembly unit 2031, and transferred to the FIFO storage unit 2032.

Referring to FIG. 4B, the trace stream generated by the timing trace generation unit 203 is illustrated. The first (in time) trace packet is generated as before. During the assembly of the second trace packet, a SYYN ID signal is generated during the third clock cycle. In response, the timing packet assembly unit 2031 assembles a packet in response to the SYNC ID signal that includes the sync ID number. The next timing packet is only partially assembled at the time of the SYNC ID signal. In fact, the SYNC ID signal occurs during the third clock cycle of the formation of this timing packet. The timing packet assembly unit 2031 generates a TIMING INDEX 3 signal (for the third packet clock cycle at which the SYNC ID signal occurs) and transmits this TIMING INDEX 3 signal to the program counter packet assembly unit 2031.

Referring to FIG. 5, the parameters of a sync marker in the program counter trace stream, according to the present invention is shown. The program counter stream sync markers each have a plurality of packets associated therewith. The packets of each sync marker can transmit a plurality of parameters. A SYNC POINT TYPE parameter defines the event described by the contents of the accompanying packets. A program counter TYPE FAMILY parameter provides a context for the SYNC POINT TYPE parameter and is described by the first two most significant bits of a second header packet. A BRANCH INDEX parameter in all but the final SYNC POINT points to a bit within the next relative branch packet following the SYNC POINT. When the program counter trace stream is disabled, this index points a bit in the previous relative branch packet when the BRANCH INDEX parameter is not a logic “0”. In this situation, the branch register will not be complete and will be considered as flushed. When the BRANCH INDEX is a logic “0”, this value point to the least significant value of branch register and is the oldest branch in the packet. A SYNC ID parameter matches the SYNC POINT with the corresponding TIMING and/or DATA SYNC POINT which are tagged with the same SYNC ID parameter. A TIMING INDEX parameter is applied relative to a corresponding TIMING SYNC POINT. For all but LAST POINT SYNC events, the first timing packet after the TIMING PACKET contains timing bits during which the SYNC POINT occurred. When the timing stream is disabled, the TIMING INDEX points to a bit in the timing packet just previous to the TIMING SYNC POINT packet when the TIMING INDEX value is nor zero. In this situation, the timing packet is considered as flushed. A TYPE DATA parameter is defined by each SYNC TYPE. An ABSOLUTE PC VALUE is the program counter address at which the program counter trace stream and the timing information are aligned. An OFFSET COUNT parameter is the program counter offset counter at which the program counter and the timing information are aligned.

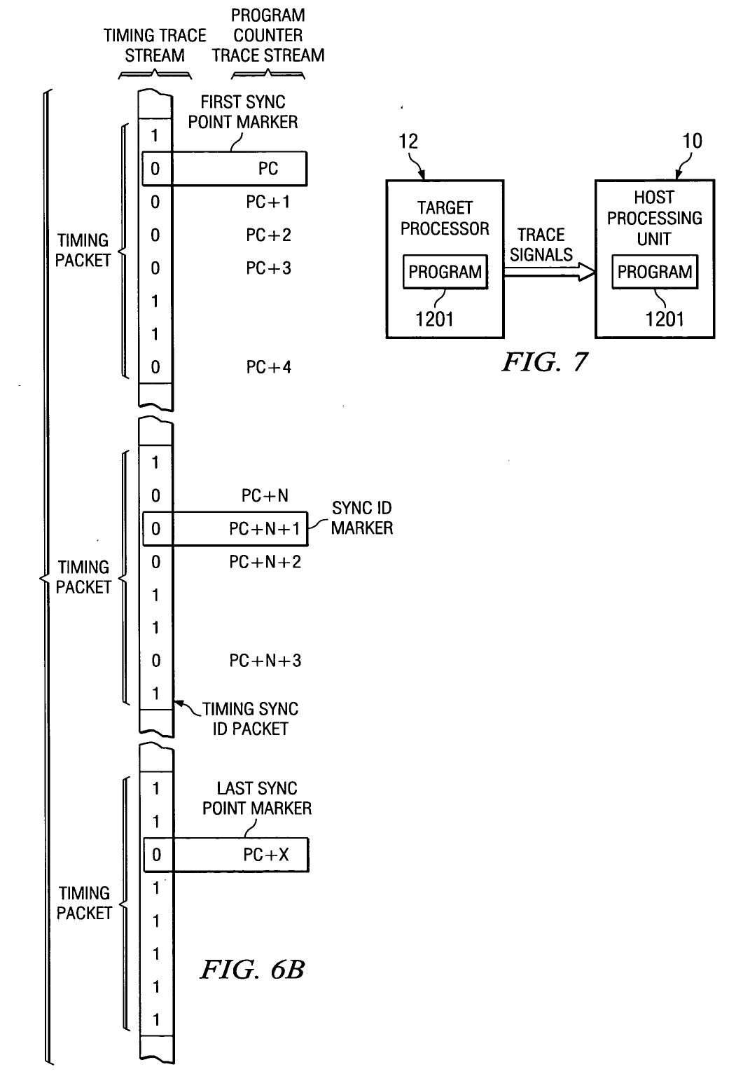

Referring to FIG. 6A, a program counter trace stream for a hypothetical program execution is illustrated. In this program example, the execution proceeds without interruption from external events. The program counter trace stream will consist of a first periodic sync point marker 601, a plurality of periodic sync point ID markers 602, and last sync point marker 603 designating the end of the test procedure. The principal parameters of each of the packets are a sync point type, a sync point ID, a timing index, and an absolute PC value. The first and last sync points identify the beginning and the end of the trace stream. The sync ID parameter is the value from the value from the most recent sync point ID generator unit. In the preferred embodiment, this value in a 3-bit logic sequence. The timing index identifies the status of the clock signals in a packet, i.e., the position in the 8 position timing packet when the event producing the sync signal occurs. And the absolute address of the program counter at the time that the event causing the sync packet is provided. Based on this information, the events in the target processor can be reconstructed by the host processor.

Referring to FIG. 6B, the reconstruction of the program execution from the timing and program counter trace streams is illustrated. The timing trace stream consists of packets of 8 logic “0”s and logic “1”s. The logic “0”s indicate that either the program counter or the pipeline is advanced, while the logic “1”s indicate the either the program counter or the pipeline is stalled during that clock cycle. Because each program counter trace packet has an absolute address parameter, a sync ID, and the timing index in addition to the packet identifying parameter, the program counter addresses can be identified with a particular clock cycle. Similarly, the periodic sync points can be specifically identified with a clock cycle in the timing trace stream. In this illustration, the timing trace stream and the sync ID generating unit are in operation when the program counter trace stream is initiated. The periodic sync point is illustrative of the plurality of periodic sync points that would typically be available between the first and the last trace point, the periodic sync points permitting the synchronization of the three trace streams for a processing unit.

Referring to FIG. 7, the general technique for reconstruction of the trace streams is illustrated. The trace streams originate in the target processor 12 as the target processor 12 is executing a program 1201. The trace signals are applied to the host processing unit 10. The host processing unit 10 also includes the same program 1201. Therefore, in the illustrative example of FIG. 6 wherein the program execution proceeds without interruptions or changes, only the first and the final absolute addresses of the program counter are needed. Using the advance/non-advance signals of the timing trace stream, the host processing unit can reconstruct the program as a function of clock cycle. Therefore, without the sync ID packets, only the first and last sync markers are needed for the trace stream. This technique results in reduced information transfer. FIG. 6 includes the presence of periodic sync ID cycles, of which only one is shown. The periodic sync ID packets are important for synchronizing the plurality of trace streams, for selection of a particular portion of the program to analyze, and for restarting a program execution analysis for a situation wherein at least a portion of the data in the trace data stream is lost. The host processor can discard the (incomplete) trace data information between two sync ID packets and proceed with the analysis of the program outside of the sync timing packets defining the lost data.

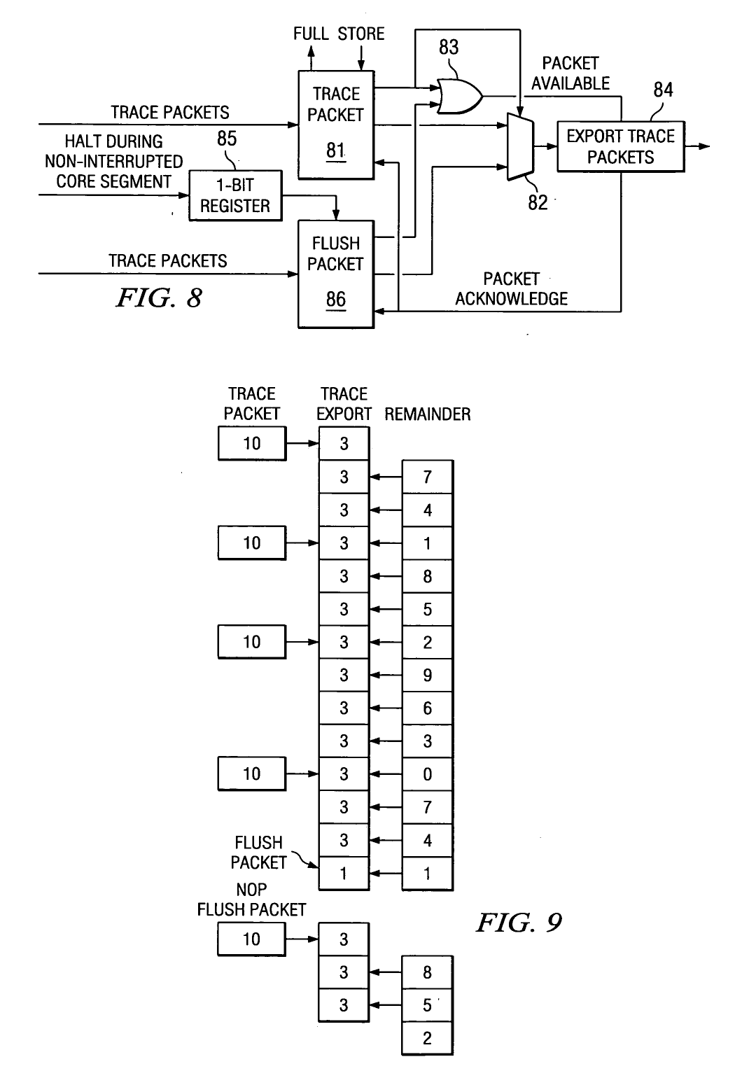

Referring to FIG. 8, the apparatus for converting the trace packets to export trace packets is shown. Trace packets are applied to trace packets unit 81. In trace packets units 81, the trace packets are grouped into export trace packets. When an export trace packet is available, a PACKET AVAILABLE signal is applied to logic “OR” gate 83 and to a control terminal of multiplexer 82. When the PACKET AVAILABLE signal is present, an export race packet is transmitted through the multiplexer 82 and applied to export trace unit 84. From export trace unit 84, the export trace packets are transferred to the host processing unit (not shown). When an export trace packet is received by the export trace unit 84, a PACKET ACKNOWLEDGE signal is applied to the trace packets unit 81 and the flush packet unit 86. 1-bit register 85 receives a HALT DURING A NON_INTERRUPTIBLE CODE SEGMENT signal. This signal sets a bit in 1-bit register 85. The bit in 1-bit register 85 applies a control signal to flush packet unit 86. The flush packet unit 86 has trace packets applied thereto and applies a PACKET AVAILABLE signal to a second input terminal of logic “OR” gate 83. In the presence of the control signal applied to flush packet unit 86, flush packets are applied through the multiplexer 82 to the export trace packet unit 84.

Referring to FIG. 9, the operation of the present invention is illustrated. The trace packets are generated and converted to export trace packets. After a halt is signaled during a non-interruptible code segment, execution of the code segment is continued until an appropriate halt point is found. The present invention, as shown in FIG. 9, stops generating trace packets. Export trace packets are generated for the trace packets that have been generated. However, when there is a remainder, the flush trace unit generates a flush packet that completes the data generated by the non-interruptible code segment. The flush packet will add logic “0”s to the incomplete packets. In addition, flush packets will be generated to provide sufficient logic signals to populate a standard memory location in the memory unit. When the target processor begins operation after a pause, the trace packets are converted into export trace packets as before.

2. Operation of the Preferred Embodiment

The present invention provides a technique for completing the transfer of trace data after the generation of halt signal for a non-interruptible code segment. Because of the nature of the code segment, the data must be transmitted as developed and not be retained in the target processor. Because the export trace packets are a different length as compared to the trace packets, the last export trace packet may not be fully populated. In the event that a remainder is present, a flush packet is generated to transfer the incomplete packet to the host processing unit. Logic “0”s complete the contents of the flush packets. In addition, flush packets are generated to insure that logic signals are available to populate the memory locations into which the packet group payloads are being entered.

The present invention relies on the ability of relate the timing trace stream and the program counter trace stream. This relationship is provided by having periodic sync ID information transmitted in each trace stream. In addition, the timing packets are grouped in packets of eight signals identifying whether the program counter or the pipeline advanced or didn't advance. The sync markers in the program counter stream include both the periodic sync ID and the position in the current eight position packet when the event occurred. Thus, the clock cycle of the event can be specified. In addition, the address of the program counter is provided in the program counter sync markers so that the debug halt event can be related to the execution of the program.

While the invention has been described with respect to the embodiments set forth above, the invention is not necessarily limited to these embodiments. Accordingly, other embodiments, variations, and improvements not described herein are not necessarily excluded from the scope of the invention, the scope of the invention being defined by the following claims.

What is claimed is:

1. In a test and debug system in which a target processor transmits trace data to a host processing unit; apparatus for transferring the data from the target processor comprising:
a trace packet unit, the trace packet unit reformatting trace packets into export trace packets; and
a flush packet unit, the flush packet unit generating a flush export trace packet when the trace packet unit does not have sufficient data to generate a trace export packet.

2. Apparatus as recited in claim 1 wherein the flush packet unit is activated in response to a halt signal during a non-interruptible code segment.

3. Apparatus as recited in claim 2 further comprising a storage unit, the storage unit storing a first signal in response to the halt signal, the first signal activating the flush packet unit.

4. Apparatus as recited in claim 3 wherein the first signal is removed when code execution resumes.

5. Apparatus as recited in claim 4 further comprising:
an export unit for transmitting export trace packets to the host processing unit; and
a switch, the switch determining whether an export trace packet or a flush export trace packet is applied to the export unit.

6. The method of generating export trace packets, the method comprising:
reformatting trace packets into export trace packets; and
generating a flush export trace packet when the data from the trace packets do not provide a complete export trace packet.

7. The method as recited in claim 6 wherein the flush export trace packet is generated after a halt signal is generated during execution of a non-interruptible code segment.

8. The method as recited in claim 7 further comprising:
storing a first signal in a storage unit as a result of a halt signal, the halt signal controlling the generation of the flush export trace packet.

9. The method as recited in claim 8 wherein the first signal is removed when the target processor begins executing code.

10. A target processor comprising:
a processing unit;
a trace unit, the trace unit coupled to the processing unit, the trace unit gathering test and debug data from the processing unit, the trace unit formatting the test and debug data in trace packets; and
a trace export unit, the trace export unit including:
a trace packet unit for converting trace packets to export trace packets; and
a flush packet unit for generating trace packets when the converting a trace packet does not result in a complete export trace packet.

11. The target processor as recited in claim 10 wherein the flush packet unit is activated in response to a halt signal during a non-interruptible code segment.

12. The target processor as recited in claim 11 wherein the trace unit further includes a storage unit, the halt signal resulting in a storage of a first signal in the storage unit, the first signal activating the flush packet unit.

13. The target processor as recited in claim 12 wherein the trace unit further includes a switch, the switch determining whether the trace packet unit or the flush trace unit is transmitted to the host processing unit.

14. The target processor as recited in claim 13 wherein the first signal is removed from the storage unit when the processor begins code execution.
